(19) United States
(12) Patent Application Publication
(10) Pub. No.: US 2005/0037550 A1
(43) Pub. Date: Feb. 17, 2005

(54) Thin film transistor using polysilicon and a method for manufacturing the same

(76) Inventors: Myung-Koo Kang, Seoul (KR); Hyun-Jae Kim, Kyungki-do (KR); Sook-Young Kang, Seoul (KR); Cheol-Ho Park, Kyungki-do (KR)

Correspondence Address: GRAY CARY WARE & FREIDENRICH LLP, 2000 UNIVERSITY AVENUE, E. PALO ALTO, CA, 94303-2248, US

(21) Appl. No.: 10/493,038

(22) PCT Filed: Jul. 9, 2002
(86) PCT No.: PCT/KR02/01298

(30) Foreign Application Priority Data
Oct. 15, 2001 (KR) 2001-63366
Apr. 1, 2002 (KR) 2002-17794

(51) Int. Cl. H01L 21/00

(52) U.S. Cl. 438/166

(57) ABSTRACT

In a method of manufacturing a thin film transistor according to the present invention, an amorphous silicon thin film is firstly formed on an insulating substrate and a planarization layer is formed thereon. Thereafter, the amorphous silicon thin film is crystallized by a solidification process using a laser-irradiation to form a polysilicon thin film. Next, the polysilicon thin film and the planarization layer are patterned to form a semiconductor layer, and a gate insulating layer covering the semiconductor layer is formed. Then, a gate electrode is formed on the gate insulating layer opposite the semiconductor layer. Next, impurities are implanted into the semiconductor layer to form a source region and a drain region opposite each other with respect to the gate electrode, and a source electrode and a drain electrode electrically connected to the source region and the drain region, respectively, are formed.

### BACKGROUND OF THE INVENTION

(a) Field of the Invention

The present invention relates to a thin film transistor with a polysilicon and a method of manufacturing the same.

(b) Description of the Related Art

In general, a liquid crystal display. (“LCD”) includes two panels with electrodes and a liquid crystal layer interposed therebetween. The two panels are combined with a sealant for sealing the liquid crystal layer, which is printed around the edges of the panels. The panels are supported by spacers distributed therebetween.

This LCD displays desired images by applying electric field using the electrodes to the liquid crystal layer with: dielectric anisotropy and adjusting the strength of the electric field to control the amount of light passing through the panels. In this case, thin film transistors (TFTs) are used for controlling signals transmitted to the electrodes.

The most commonly used TFTs for an LCD adapts amorphous silicon as a semiconductor layer.

An amorphous silicon TFT has mobility of about 0.5 to 1 cm²/Vsec, which is suitable for a switching element of an LCD. However, it is not sufficient for a driving circuit of a display device such as an LCD or an organic EL (electro luminescent) device.

In order to overcome such a problem, an organic EL or a polysilicon TFT LCD using a polysilicon with electron mobility of 20 to 150 cm²/Vsec as a semiconductor layer has been developed. The relatively high electron mobility polysilicon TFT enables to implement a chip in glass technique that a display panel embeds its driving circuits.

In recent years, one of the most widely used methods of forming a polysilicon thin film on a glass substrate with a low melting point is an eximer laser annealing technique. The technique irradiates light with the wavelength, which can be absorbed by amorphous silicon, from an eximer laser into a amorphous silicon layer deposited on a substrate to melt the amorphous silicon layer at 1,400° C., thereby crystallizing the amorphous silicon into polysilicon. The crystal grain has a relatively uniform size ranging about 3,000-5,000 Å, and the crystallization time is only about 30-200 nanoseconds, which does not damage the glass substrate. However, there are disadvantages that non-uniform grain boundaries decrease the uniformity for electrical characteristics between the TFTs and make it hard to adjust the microstructure of the grains.

To solve these problems, a sequential lateral solidification process capable of adjusting the distribution of the grain boundaries has been developed. The process is based on the fact that the grains of polysilicon at the boundary between a liquid phase region exposed to laser beam and a solid phase region not exposed to laser beam grow in a direction perpendicular to the boundary surface. A mask having a slit pattern is provided, and a laser beam passes through transmittance areas of the mask to completely melt amorphous silicon, thereby producing liquid phase regions arranged in a slit pattern. Thereafter, the melted amorphous silicon cools down to be crystallized; and the crystal growth starts from the boundaries of the solid phase regions not exposed to the laser beam, and proceeds in the directions perpendicular to the boundary surface. The grains stop growing when they encounter each other at the center of the liquid phase region. This process is repeated after moving the slit pattern of the mask in the direction of the grain growth, and thus the sequential lateral solidification covers the whole area. The sizes of the grains can be as much as the widths of the slit pattern. After crystallization, protuberances of about 400-1,000 Å are formed on the surface along the grain boundaries. These causes stress on the boundary surface of a gate insulating layer to be formed on the semiconductor layer. The stress in this process is found to be ten times more than that in the eximer laser annealing, and this results in degrading the characteristics of the TFTs.

To solve these problems, it is suggested a method forming an oxide film on the polysilicon thin film by oxidization, and removing the oxide film to smooth the surface of the semiconductor layer.

However, this method, which relates to removal of the protuberances once formed, has a problem it is very difficult to determine oxidizing conditions or etching conditions for removing the oxide film.

### SUMMARY OF THE INVENTION

All object of the present invention is to provide a polysilicon TFT and a manufacturing method thereof, which is capable of restraining the growth of protuberances generated in a poly-crystallization step.

To accomplish the object, in the present invention, a buffer layer is formed on a semiconductor layer of amorphous silicon, and the amorphous silicon layer is crystallized into a polysilicon layer by performing eximer laser crystallization or lateral solidification.

In a method of manufacturing a thin film transistor according to the present invention, an amorphous silicon thin film is firstly formed on an insulating substrate, and a planarization layer is formed thereon. The amorphous silicon thin film is crystallized by solidification with laser-irradiation to form a polysilicon thin film. Next, the polysilicon thin film is patterned to form a semiconductor layer. A gate insulating layer covering the semiconductor layer is formed, and a gate electrode is formed on the gate insulating layer opposite the semiconductor layer. Next, impurities are implanted into the semiconductor layer to form a source region and a drain region opposite each other with respect to the gate electrode, and a source electrode and a drain electrode electrically connected to the source region and the drain region, respectively, are formed.

A passivation layer having a contact hole exposing the drain electrode and a pixel electrode connected to the drain electrode are preferably further formed. The passivation layer is preferably made of silicon nitride, SiOC, SiOF or an organic insulating material.

Now, a polysilicon TFT and a manufacturing method thereof according to embodiments of the present invention will be described with reference to the drawings, which enable those skilled in the art to easily carry out the present invention.

According to an embodiment of the present invention, amorphous silicon is partially irradiated with an eximer laser beam such that portions of the amorphous silicon exposed to the laser beam is completely melted to form liquid phase regions. The melted amorphous silicon is then cooled down to be crystallized. Alternatively, amorphous silicon is crystallized into polysilicon by a lateral solidification process. That is, amorphous silicon is completely melted to form a plurality of liquid phase regions arranged in a slit: pattern by passing a laser beam through transmitting areas of a mask with a slit pattern. Thereafter, grains, grow in the directions perpendicular to the boundaries of solid phase regions.

The eximer laser crystallization or the lateral solidification is performed after forming a buffer layer on the amorphous silicon so as to restrain the growth of the protuberances generated along the grain boundaries. It is described in detail with reference to the drawings.

### BRIEF DESCRIPTION OF THE DRAWINGS

FIG. 1 is a sectional view illustrating a structure of a polysilicon TFT according to an embodiment of the present invention.

FIGS. 2A to 2F are sectional views of a polysilicon TFT in the steps of a manufacturing method thereof according to an embodiment of the present invention.

### DETAILED DESCRIPTION OF PREFERRED EMBODIMENTS

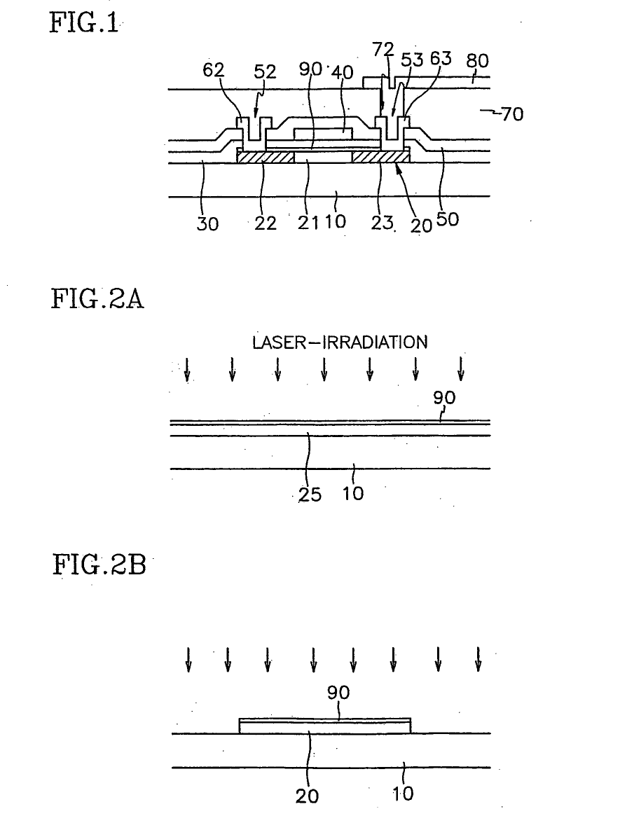

First, a structure of a polysilicon TFT according to an embodiment of the present invention will be described with reference to FIG. 1.

FIG. 1 is a sectional view illustrating a structure of a polysilicon TFT according to an embodiment of the present invention.

As shown in FIG. 1, a semiconductor layer 20 made of polysilicon is formed on an insulating substrate 10. The semiconductor layer 20 includes a channel region 21 and source and drain regions 22 and 23 opposite each other with respect to the channel, region 21. Here, the source and the drain regions 22 and 23 are doped with n type or p type impurity and may include a silicide layer. Furthermore, a planarization film 90 is formed on the semiconductor layer 20 so as to prevent the protuberance formation along the grain boundaries on the surface of the semiconductor layer 20 in the manufacturing process. The planarization film 90 is preferably made of dielectric material capable of transmitting laser beam, such as silicon oxide (SiO₂) or silicon nitride (SiₓN_{y}). The thickness of the planarization film 90 is preferably in a range of 100-1,5000 Å.

A gate insulating layer preferably made of SiO₂ or SiNₓ and covering the semiconductor layer 20 is formed on the substrate 10, and a gate electrode 40 is formed on the gate insulating layer 30 opposite the channel region 21. Although not shown in the drawings, a gate line connected to the gate electrode is preferably added on the gate insulating layer 30.

An interlayer insulating layer 50 covering the gate electrode 40 is formed on the gate insulating layer 30, and the gate insulating layer 30 and the interlayer insulating layer 50 have contact holes 52 and 53 exposing the source and the drain regions 22 and 23.

A source electrode 62 and a drain electrode 63 are formed on the interlayer insulating layer 50. The source electrode 62 is connected to the source region 22 via the contact hole 52, and a drain electrode 63 is opposite the source electrode 62 with respect to the gate electrode 40 and connected to the drain region 23 via the contact hole 53. On the interlayer insulating layer 50, although not shown in the drawings, a data line connected to the source electrode 62 is preferably added.

A passivation layer 70 made of silicon nitride, SiOC, SiOF or organic insulating material is formed on the interlayer insulating layer 50. A pixel electrode 80 connected to the drain electrode 63 via a contact hole 72 in the passivation layer 70 is formed on the passivation layer 70.

A buffer layer may be provided between the substrate 10 and the semiconductor layer 20 in this TFT.

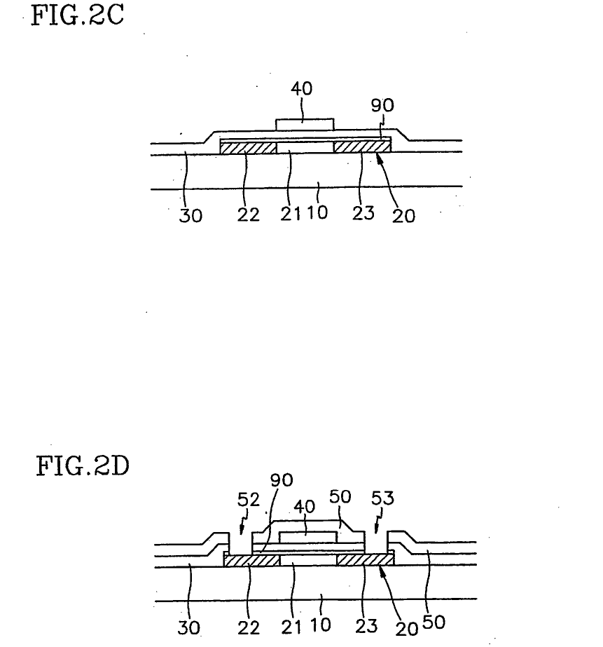

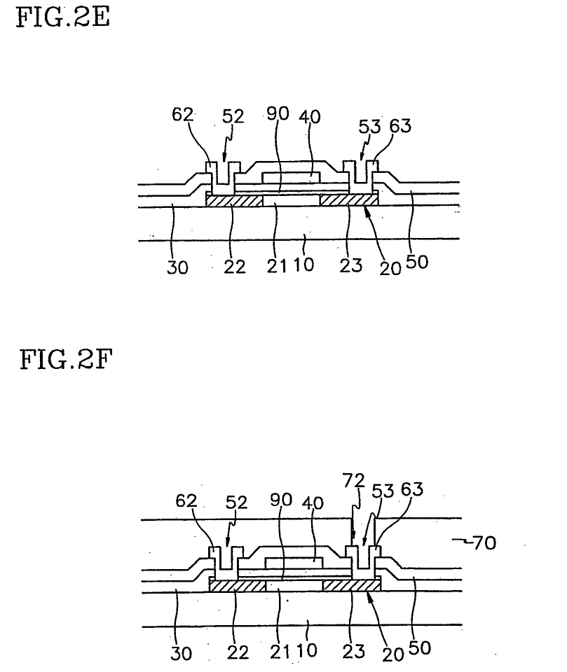

Next, a method of manufacturing a polysilicon TFT according to an embodiment of the present invention will be described with reference to FIG. 1 and FIGS. 2A to 2F.

FIGS. 2A to 2F are sectional views of a polysilicon TFT in the steps of a manufacturing method thereof according to an embodiment of the present invention.

First, as shown in FIG. 2A, a thin film of amorphous silicon is deposited by low pressure chemical vapor deposition (“CVD”), plasma enhanced CVD or sputtering, and then, silicon nitride with the thickness of about 1,000 Å is deposited to form a planarization layer 90. Thereafter, a polysilicon thin film 25 is formed using eximer laser crystallization or lateral solidification process. That is, the amorphous silicon thin film is irradiated with a laser beam to be melt into a liquid phase, and then, cooled down to form grains. This process, which performs poly-crystallization after forming the planarization layer 90 on the amorphous silicon thin film as in the method according to the present invention, restrains the protuberance growth on the surface of the polysilicon thin film 25.

Silicon oxide or silicon nitride is preferably used as dielectric material of the planarization layer 90, and the thickness of the dielectric material is preferably in a range between 100-1,500 Å. When completely melting the amorphous silicon by using high energy, the thickness of the planarization layer 90 equal to about 1,000 Å is the most effective in smoothing the polysilicon thin film 25, while 100-200 Å thickness is the most effective when partially melting the amorphous silicon by using low energy.

In an experiment, which crystallized amorphous silicon to form a polysilicon thin film 25 after forming the planarization layer 90, the roughness of the surface was measured to be equal to or less than 100 Å, and shot marks occurring in irradiating laser beam was confirmed to be disappeared.

Next, as shown in FIG. 2B, the polysilicon thin film 25 and the planarization layer 90 thereunder are patterned by a photo etching process using an active mask to form a semiconductor layer 20.

Then, as shown in FIG. 2C, silicon oxide or silicon nitride is deposited to form a gate insulating layer 30, and then, a conductive material for a gate wire is deposited and patterned to form a gate electrode 40 on a channel region 21 of the semiconductor layer 20. Next, p type or n type impurities are ion-implanted into the semiconductor layer 20 using the gate electrode 40 as a mask, and activated to form source and drain regions 22 and 23 opposite each other with respect to the channel region 21.

Next, as shown in FIG. 2D, an interlayer insulating layer 50 covering the gate electrode 40 is formed on the gate insulating layer 30, and then, the interlayer insulating layer 50 as well as the gate insulating layer 30 and the planarization layer 90 is patterned to form contact holes 52 and 53 exposing the source and the drain regions 22 and 23 of the semiconductor layer 20.

Next, as shown in FIG. 2E, a metal for a data wire is deposited on the insulating substrate 10 and patterned to form a source electrode 62 and a drain electrode 63 connected to the source region 22 and the drain region 23 via the contact holes 52 and 53, respectively.

Next, as shown in FIG. 2F, an insulating material is deposited on the insulating substrate 10 to form a passivation, layer 70, and then patterned to form a contact hole 72 exposing the drain electrode 63.

Next, as shown in FIG. 1, a transparent conductive material such as ITO (indium tin oxide) or IZO (indium zinc oxide), or a reflective conductive material is deposited and patterned to form a pixel electrode 80.

Although the accomplished TFT in this embodiment has the planarization layer 90, the planarization layer 90 may be removed or replaced with the gate insulating layer.

In addition, although the manufacturing process of the TFT has been described to include the step of forming the pixel electrode, the technique of the present invention is also applicable to a manufacturing process of a polysilicon thin film used as a switching element of a display device such as an organic EL device.

As described above, the present invention performs poly-crystallization step after depositing a planarization layer on an amorphous silicon layer. This restrains the protuberance formation on the surface of the semiconductor layer to increase the surface uniformity, thereby improving the characteristics of a TFT and a display device including the same.

1. A thin film transistor comprising:
a semiconductor layer made of polysilicon and including a channel region and source and drain regions opposite each other with respect to the channel region;
a planarization layer formed on the semiconductor layer;
a gate insulating layer covering the semiconductor layer and the planarization layer; and
a source electrode and a drain electrode connected to the source region and the drain region, respectively.

2. The thin film transistor of claim 1, further comprising:
a pixel electrode connected to the drain electrode; and
a passivation interposed between the drain electrode and the pixel electrode and made of silicon nitride, SiOC, SiOF or an organic insulating material.

3. The thin film transistor of claim 1, wherein the planarization layer is made of silicon oxide or silicon nitride.

4. The thin film transistor of claim 1, wherein thickness of the planarization layer is in a range of 100-1,500 Å.

5. The thin film transistor of claim 1, wherein the thin film transistor is adapted for a switching element of a liquid crystal display.

6. The thin film transistor of claimed wherein the thin film transistor is adapted for a switching element of an organic EL.

7. A method of manufacturing a thin film transistor of a display comprising:
forming an amorphous silicon thin film on an insulating substrate;
depositing silicon oxide or silicon nitride on the amorphous silicon thin film to form a planarization layer;
forming a polysilicon thin film by irradiating the amorphous silicon thin film with a laser beam and crystallizing the amorphous silicon thin film;
patterning the polysilicon thin film to form a semiconductor layer;
forming a gate insulating layer covering the semiconductor layer;
forming a gate electrode on the gate insulating layer opposite the semiconductor layer;
implanting impurities into the semiconductor layer to form a source region and a drain region opposite each other with respect to the gate electrode; and
forming a source electrode and a drain electrode electrically connected to the source region and the drain region, respectively.

8. The method of claim 7, further comprising:
forming a passivation layer having a contact hole exposing the drain electrode; and
forming a pixel electrode connected to the drain electrode via the contact hole.

9. The method of claim 7, wherein thickness of the planarization layer is in a range of 100-1,500 Å.

10. The method of claim 7, further comprising removing the planarization layer after the formation of the polysilicon thin film.

11. The method of claim 7, wherein the display is a liquid crystal display or an organic EL device.
